(19) United States
(12) Patent Application Publication
(10) Pub. No.: US 2013/0068163 A1
(43) Pub. Date: Mar. 21, 2013

(54) FILM DEPOSITION APPARATUS

(71) Applicants: Tatsuya YAMAGUCHI, Yamanashi (JP); Masafumi Ishida, Yamanashi (JP); Hiroyuki Hashimoto, Yamanashi (JP); Shigure Ohmukai, Yamanashi (JP); Atsushi Ando, Yamanashi (JP)

(72) Inventors: Tatsuya YAMAGUCHI, Yamanashi (JP); Masafumi Ishida, Yamanashi (JP); Hiroyuki Hashimoto, Yamanashi (JP); Shigure Ohmukai, Yamanashi (JP); Atsushi Ando, Yamanashi (JP)

(73) Assignee: Tokyo Electron Limited, Tokyo (JP)

(21) Appl. No.: 13/425,483

(22) Filed: Mar. 21, 2012

(30) Foreign Application Priority Data
Mar. 24, 2011 (JP) 2011-066461

(51) Int. Cl. C23C 16/02

(52) U.S. Cl. 118/725

(57) ABSTRACT

A film deposition apparatus includes a film deposition chamber into which a substrate is carried, a heating mechanism that heats the substrate carried into the film deposition chamber, an adhesion accelerating agent feed mechanism that feeds an adhesion accelerating agent gas into the film deposition chamber, and a control part that controls the heating mechanism and the adhesion accelerating agent feed mechanism. When depositing a polyimide film on the substrate by feeding a first source gas formed of dianhydride and a second source gas formed of diamine into the film deposition chamber, the control part is configured to control the adhesion accelerating agent feed mechanism to treat a surface of the substrate with the adhesion accelerating agent gas by feeding the adhesion accelerating agent gas into the film deposition chamber until the substrate is heated to a predetermined temperature for depositing the polyimide film.

### CROSS-REFERENCE TO RELATED APPLICATION

The present application is based upon and claims the benefit of priority of Japanese Patent Application No. 2011-066461, filed on Mar. 24, 2011, the entire contents of which are incorporated herein by reference.

### BACKGROUND OF THE INVENTION

1. Field of the Invention

The present invention relates to a film deposition apparatus for depositing a film on a substrate.

2. Description of the Related Art

In recent years, a wide range of materials from inorganic materials to organic materials are used for a semiconductor device. The characteristics of the organic materials (of which inorganic materials do not have) help to optimize the properties of the semiconductor device and the manufacturing process of the semiconductor device.

One of the organic materials is polyimide. Polyimide has a high insulating property. Therefore, a polyimide film obtained by depositing polyimide on a surface of a substrate can be used as an insulating film, and as an insulating film of a semiconductor device.

As a method for depositing the polyimide film, there is known film deposition method where vapor deposition polymerization is performed by using, for example, pyromellitic dianhydride (PMDA) and 4,4′-oxydianiline (ODA) as raw material monomers. Vapor deposition polymerization is a method that causes thermal polymerization of pyromellitic dianhydride (PMDA) and 4,4′-oxydianiline (ODA) (being used as raw material monomers) on a surface of a substrate (see, for example, Japanese Patent No. 4283910). Japanese Patent No. 4283910 discloses a film deposition method where a polyimide film is deposited by vaporizing PMDA and ODA monomers in a vaporizer, feeding each of the vaporized gases to a vapor deposition polymerization chamber, and causing vapor deposition polymerization on a substrate.

However, the film deposition apparatus which deposits a polyimide film by supplying the above-described PMDA gas and ODA gas to the substrate has the following problems.

In order to improve the film quality of the polyimide film deposited on the substrate, it is necessary to perform surface treatment using an adhesion accelerating agent before film deposition and perform imidization by thermal treatment after film deposition.

The surface treatment using the adhesion accelerating agent may be performed by treating the surface of the substrate with an adhesion accelerating agent (e.g., silane coupling agent) before depositing the polyimide film. Thereby, the adhesive strength of the deposited polyimide film can be improved. However, in a case where the surface treatment using the adhesion accelerating agent in a container separate from a film deposition chamber used for depositing the polyimide film is performed before depositing the polyimide film, a processing time becomes longer because the number of steps is increased. As a result, the number of substrates that can be processed per unit of time decreases.

Further, the purpose of performing imidization by thermal treatment after the film deposition is for increasing the imidization rate (ratio of polyimide in the film) by further performing thermal treatment after the polyimide film is deposited. Thereby, the insulating property of the deposited polyimide film can be improved. However, a long time is necessary to increase the temperature of the substrate by heating the substrate in a case of performing the thermal treatment with a batch-type thermal treatment apparatus (e.g., vertical furnace) on the substrate mounted on a boat and conveyed out from the film deposition chamber after having a film deposited thereon.

On the other hand, in a case of performing the thermal treatment with a single-wafer type thermal treatment apparatus (e.g., hot plate), the time for performing the thermal treatment is shorter compared to performing thermal treatment with a batch-type thermal treatment apparatus. However, due to the single-wafer type process, an extremely long time is required for processing an entire lot of substrates (wafers). As a result, the number of substrates that can be subjected to the film deposition process per unit of time (throughput) decreases.

### SUMMARY OF THE INVENTION

In view of the above, an embodiment of the present invention provides a film deposition apparatus that can improve film quality of a deposited polyimide film and increase the number of substrates subjected to the film deposition process per unit of time.

According to an embodiment of the present invention, there is provided a film deposition apparatus including: a film deposition chamber into which a substrate is carried; a heating mechanism that heats the substrate carried into the film deposition chamber; an adhesion accelerating agent feed mechanism that feeds an adhesion accelerating agent gas into the film deposition chamber; and a control part that controls the heating mechanism and the adhesion accelerating agent feed mechanism; wherein when depositing a polyimide film on the substrate by feeding a first source gas formed of dianhydride and a second source gas formed of diamine into the film deposition chamber, the control part is configured to control the adhesion accelerating agent feed mechanism to treat a surface of the substrate with the adhesion accelerating agent gas by feeding the adhesion accelerating agent gas into the film deposition chamber until the substrate is heated to a predetermined temperature for depositing the polyimide film.

The object and advantages of the present invention will be realized and attained by means of the elements and combinations particularly pointed out in the claims.

It is to be understood that both the foregoing general description and the following detailed description are exemplary and explanatory and not restrictive of the invention as claimed.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention, in which:

FIG. 1 is a schematic longitudinal cross-sectional view of a film deposition apparatus according to an embodiment of the present invention;

FIG. 2 is a schematic perspective view of a loading area according to an embodiment of the present invention;

FIG. 3 is a perspective view of a boat according to an embodiment of the present invention;

FIG. 4 is a cross-sectional view of a configuration of a film deposition chamber according to an embodiment of the present invention;

FIG. 5 is a schematic diagram illustrating a configuration of a cooling mechanism according to an embodiment of the present invention;

FIG. 6 is a schematic diagram illustrating a configuration of an adhesion accelerating agent feed mechanism according to an embodiment of the present invention;

FIG. 7 is a flowchart for describing steps of a film deposition process using a film deposition apparatus according to an embodiment of the present invention;

FIGS. 8A-8B are graphs for describing a method of controlling a heater and a cooling mechanism according to an embodiment of the present invention;

FIGS. 9A-9B are schematic diagrams illustrating a reaction on a surface of a wafer in a case where a silane coupling agent is used as an adhesive accelerating agent according to an embodiment of the present invention;

FIGS. 10A-10B are schematic diagrams illustrating a reaction on a surface of a wafer of a comparative example in a case where a silane coupling agent and water vapor are used;

FIG. 11 is a schematic diagram illustrating a reaction on a surface of a wafer of another comparative example in a case where a silane coupling agent and water vapor are used;

FIG. 12 is a schematic diagram illustrating the state of a surface of a wafer in a case where the wafer is cleaned with ammonia peroxide (SC 1) and the surface of the wafer is terminated with a hydroxyl group after dilute hydrofluoric (DHF);

FIG. 13 is a time chart illustrating a comparison between a film deposition process according to an embodiment of the present invention and a film deposition process according to a comparative example;

FIGS. 14A-14B are graphs illustrating the dependency of imidization rate of a polyimide film with respect to a film deposition temperature and a thermal treatment temperature;

FIGS. 15A and 15B are graphs illustrating a comparison between a case of using a cooling mechanism and a case of not using a cooling mechanism where temperature is measured by a temperature sensor provided in a film deposition chamber during a period between carrying a boat into a film deposition chamber and carrying the boat out from a film deposition chamber;

FIG. 16 is a flowchart illustrating steps included in a film deposition process performed by a film deposition apparatus according to a modified example of an embodiment of the present invention; and

FIG. 17 is a cross-sectional view illustrating a configuration of a film deposition chamber according to another embodiment of the present invention.

### DETAILED DESCRIPTION OF THE PREFERRED EMBODIMENT

Next, a description is given of embodiments of the present invention with reference to the accompanying drawings.

### First Embodiment

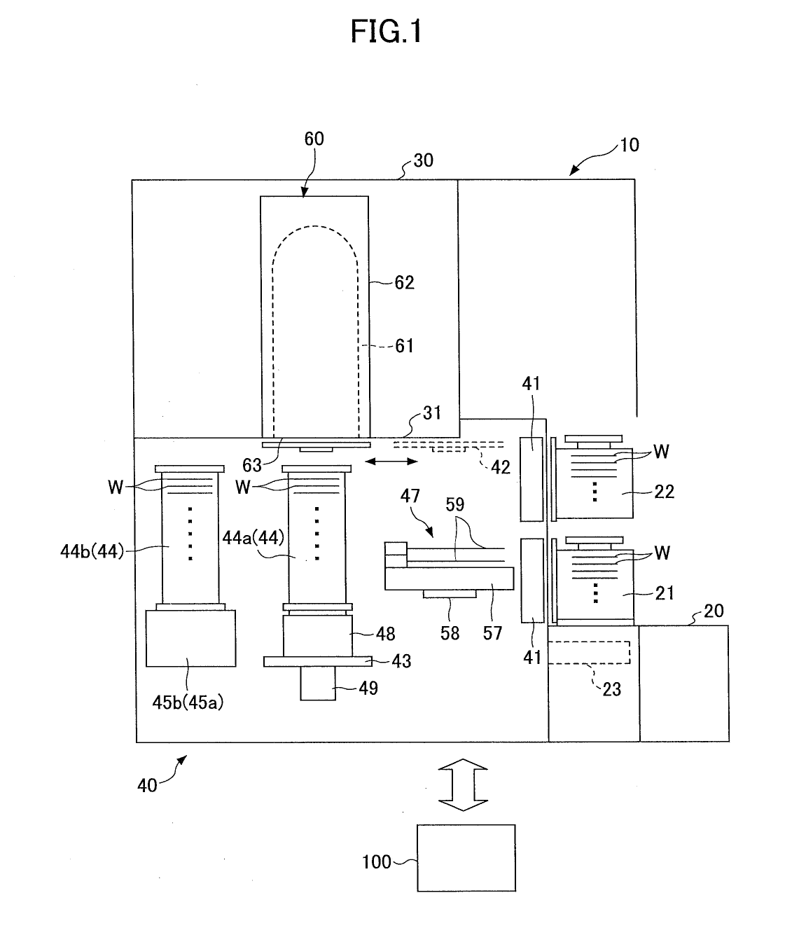

First, a description is given, with reference to FIG. 1 through FIG. 15B, of a film deposition apparatus according to the first embodiment of the present invention.

The film deposition apparatus according to this embodiment may be applied to a film deposition apparatus configured to deposit a polyimide film on a substrate held in a film deposition chamber by feeding the substrate with a first raw material gas, which is, for example, vaporized pyromellitic dianhydride (hereinafter abbreviated as “PMDA”), and a second raw material gas, which is, for example, vaporized 4,4′-3 oxydianiline (hereinafter, abbreviated as “ODA”).

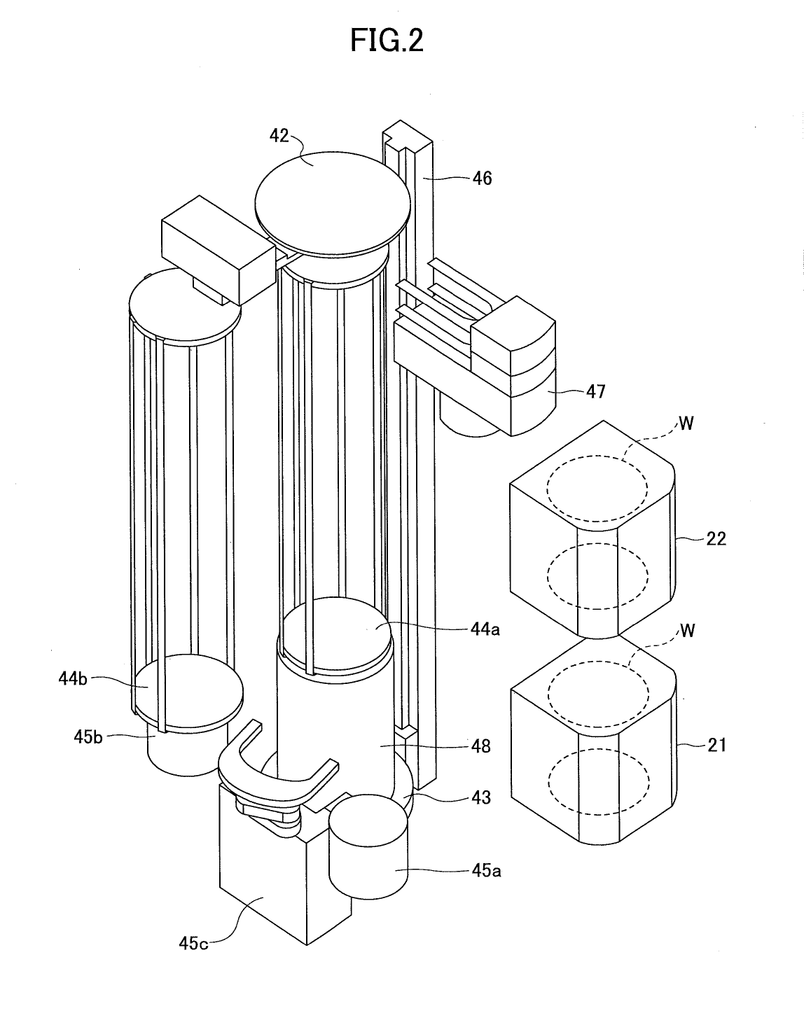

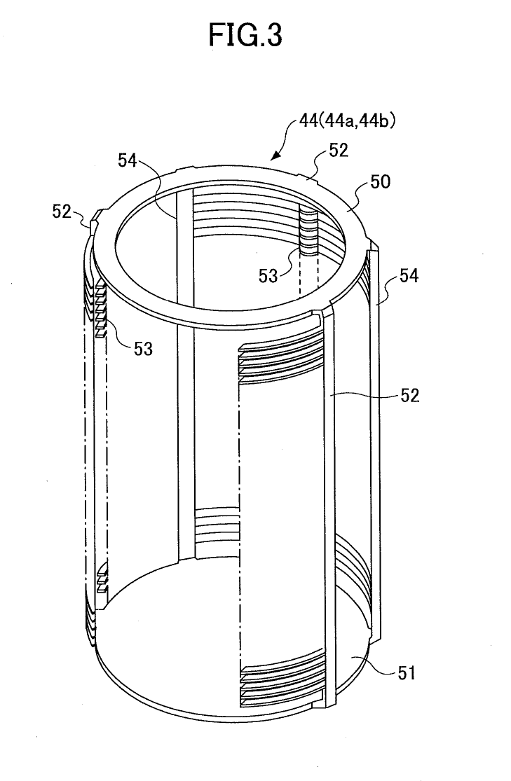

FIG. 1 is a schematic longitudinal cross-sectional view illustrating a film deposition apparatus 10 according to this embodiment. FIG. 2 is a schematic perspective view of a loading area 40. FIG. 3 is a perspective view illustrating an example of a boat 44.

The film deposition apparatus 10 includes a placement table (load port) 20, a housing 30, and a control part 100.

The placement table 20 is provided on the front side of the housing 30. The housing 30 includes the loading area (work area) 40 and the film deposition chamber 60. The loading area 40 is provided in a lower part of the housing 30. The film deposition chamber 60 is provided above the loading area 40 in the housing 30. Further, a base plate 31 is provided between the loading area 40 and the film deposition chamber 60. The below-described feed mechanism 70 is provided in a manner connected to the film deposition chamber 60.

The base plate 31 is, for example, a stainless steel base plate for providing a reaction tube 61 of the film deposition chamber 60. An opening, which is not graphically illustrated, is formed in the base plate 31 to allow insertion of the reaction tube 61 from the bottom up.

The placement table 20 is for carrying the wafers W into and out of the housing 30. Containers 21 and 22 are placed on the placement table 20. The containers 21 and 22 are closable containers (front-opening unified pods or FOUPs) each having a detachable lid, which is not graphically illustrated, on the front and can accommodate multiple, for example, approximately 50 wafers at predetermined intervals.

Further, an aligning unit (aligner) 23 configured to align notched parts (notches) provided in the peripheries of the wafers W transferred by the below-described transfer mechanism 47 in a single direction may be provided below the placement table 20.

The loading area 40 is a work area for transferring the wafers W between the containers 21, 22 and the boat 44, carrying (loading) the boat 44 into the film deposition chamber 60, and carrying out (unloading) the boat 44 from the film deposition chamber 60. Door mechanisms 41, a shutter mechanism 42, a lid body 43, the boat 44, bases 45a and 45b, an elevation mechanism 46, and the transfer mechanism 47 are provided in the loading area 40.

It is to be noted that the lid body 43 and the boat 44 may correspond to a substrate holding part according to an aspect of the present invention.

The door mechanisms 41 are configured to remove the lids of the containers 21 and 22 to cause the containers 21 and 22 to communicate with and be open to the inside of the loading area 40.

The shutter mechanism 42 is provided in an upper part of the loading area 40. The shutter mechanism 42 is so provided as to cover (or close) the below-described opening 63 of the film deposition chamber 60 to control or prevent a release of the heat inside the film deposition chamber 60 at high temperature to the loading area 40 through the opening 63 when the lid body 43 is open.

The lid body 43 includes a heat insulating tube 48 and a rotation mechanism 49. The heat insulating tube 48 is provided on the lid body 43. The heat insulating tube 48 prevents the boat 44 from being cooled through a transfer of heat with the lid body 43, and keeps heat in the boat 44. The rotation mechanism 49 is attached to the bottom of the lid body 43. The rotation mechanism 49 causes the boat 44 to rotate. The rotating shaft of the rotation mechanism 49 is so provided as to pass through the lid body 43 in a hermetic manner to rotate a rotating table, which is not graphically illustrated, provided on the lid body 43.

The elevation mechanism 46 drives the lid body 43 to move up and down when the boat 44 is carried into the film deposition chamber 60 from the loading area 40 and out of the film deposition chamber 60 to the loading area 40. The lid body 43 is provided so as to come into contact with the opening 63 to hermetically close the opening 63 when the lid body 43, moved upward by the elevation mechanism 46, has been carried into the film deposition chamber 60. The boat 44 placed on the lid body 43 may hold the wafers W in the film deposition chamber 60 in such a manner as to allow the wafers W to rotate in a horizontal plane.

The film deposition apparatus 10 may have multiple boats 44. In this embodiment, a description is given below, with reference to FIG. 2, of a case where the film deposition apparatus 10 includes two boats 44a and 44b, which may also be collectively referred to as the “boat 44” when there is no need to make a distinction between the boats 44a and 44b in particular.

The boats 44a and 44b are provided in the loading area 40. The bases 45a and 45b and a boat conveying mechanism 45c are provided in the loading area 40. The bases 45a and 45b are placement tables onto which the boats 44a and 44b are transferred from the lid body 43, respectively. The boat conveying mechanism 45c transfers the boats 44a and 44b from the lid body 43 to the bases 45a and 45b, respectively.

The boats 44a and 44b are made of, for example, quartz, and are configured to have the wafers W, which are large, for example, 300 mm in diameter, loaded in a horizontal position at predetermined intervals (with predetermined pitch width) in a vertical direction. For example, as illustrated in FIG. 3, the boats 44a and 44b have multiple, for example, three columnar supports 52 are provided between a top plate 50 and a bottom plate 51. The columnar supports 52 are provided with claw parts 53 for holding the wafers W. Further, auxiliary columns 54 may suitably be provided together with the columnar supports 52.

The transfer mechanism 47 is configured to transfer the wafers W between the containers 21 and 22 and the boats 44 (44a and 44b). The transfer mechanism 47 includes a base 57, an elevation arm 58, and plural forks (transfer plates) 59. The base 57 is so provided as to be vertically movable and turnable. The elevation arm 58 is, for example, so provided as to be vertically movable (movable upward and downward) with a ball screw or the like. The base 57 is so provided as to be horizontally movable (turnable) relative to the elevation arm 58.

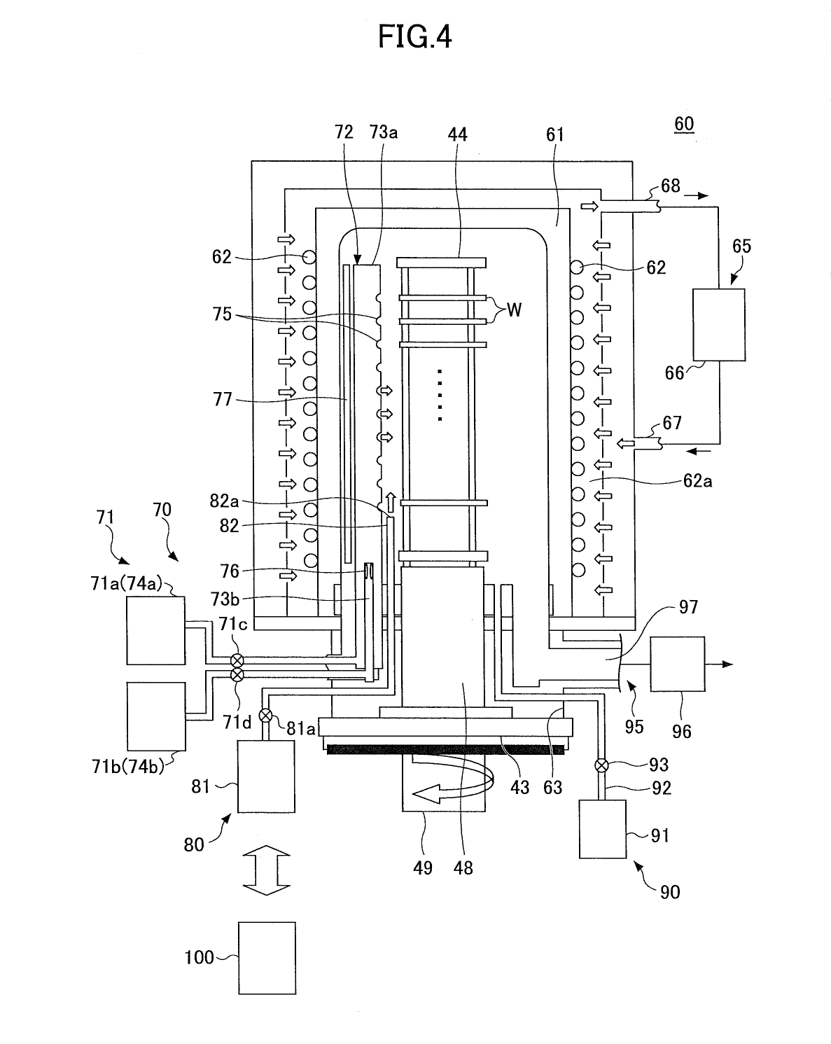

FIG. 4 is a cross-sectional view illustrating a configuration of the film deposition chamber 60 according to an embodiment of the present invention.

The film deposition chamber 60 may be, for example, a vertical furnace that accommodates multiple substrates to be processed (treated), such as thin disk-shaped wafers W, and performs a predetermined process such as CVD on the substrates to be processed. The film deposition chamber 60 includes the reaction tube 61, a heater (heating mechanism) 62, a cooling mechanism 65, a feed mechanism 70, adhesion accelerating agent feed mechanism 80, a purge gas feed mechanism 90, and an exhaust mechanism 95.

It is to be noted that the heater 62 may correspond to a heating mechanism according to an aspect of the present invention.

The reaction tube 61 is made of, for example, quartz, has a vertically elongated shape, and has the opening 63 formed at the lower end. The heater (heating mechanism) 62 is so provided as to cover the periphery of the reaction tube 61, and may control heating so that the inside of the reaction tube 61 is heated to a predetermined temperature, for example, 50° C. to 1200° C. It is to be noted that the temperature of the wafer W inside the reaction tube 61 may be controlled by an injector heater 77 that controls the temperature inside the below-described injector 72. The injector heater 77 may be provided in the vicinity of the heater 62 covering the periphery of the reaction tube 61 and the injector 72.

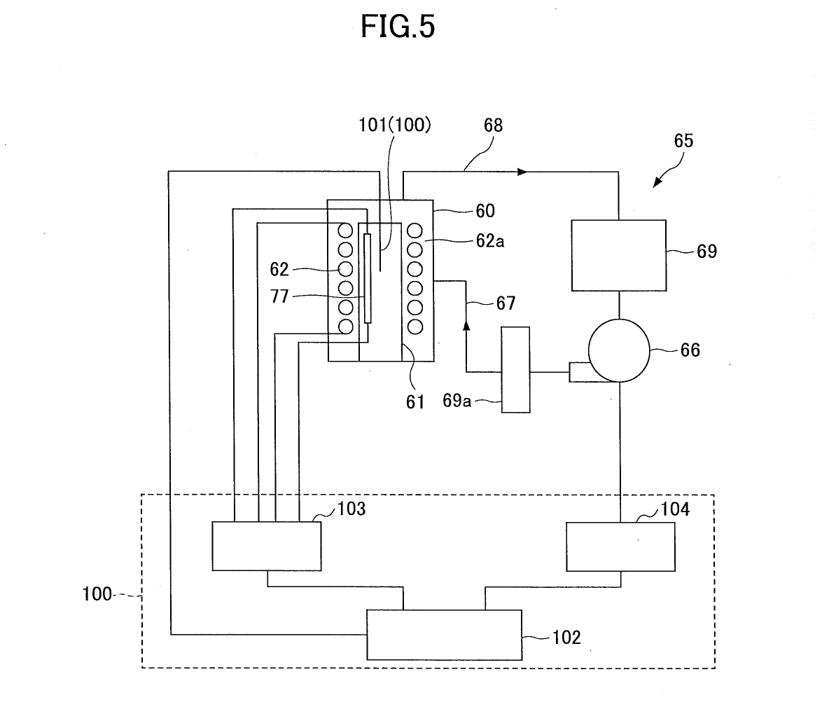

FIG. 5 is a schematic diagram illustrating a configuration of the cooling mechanism 65 according to an embodiment of the present invention.

The cooling mechanism 65 includes a blower (air-blower) 66, an air blow tube 67, and an exhaust tube 68. The blower 66 is for blowing air into a space 62a provided inside the heater 62 and cooling the film deposition chamber 60. The air blow tube 67 is for delivering air from the blower 66 to the heater 62. The air blow tube 67 is connected to the space 62a. The exhaust tube 68 is for evacuating the air (gas) inside the heater 62. The exhaust tube 68 is also connected to the space 62a.

It is to be noted that the gas inside the space 62a may be evacuated from the exhaust tube 68 to a factory exhaust system via a thermal exchange apparatus 69. Alternatively, as illustrated in FIG. 5, instead of evacuating the gas from the factory exhaust system, the thermal exchange apparatus 69 may be provided, so that the gas may be heated by the thermal exchange apparatus 69, returned to the intake side of the blower 66, and circulated for use. In the alternative case, it is preferable for the gas to be circulated via an air filter 69a. Although the air filter 69a may be provided on the intake side of the blower 66, it is more preferable for the air filter 69a to be provided on the blowout side of the blower 66. The thermal exchange apparatus 69 is for making use of the heat exhausted from the heater 62.

The film deposition apparatus according to an embodiment of the present invention may have a temperature sensor 101 and a temperature controller 102 as a part of the below-described control part 100.

The temperature sensor 101 is for detecting the temperature inside the film deposition chamber 60 (temperature of the wafer W). The temperature controller 102 is a control device for controlling the power to be fed to the heater 62 and the blower 66 while feeding back the temperature detected by the temperature sensor 101. Signals from the temperature sensor are input to the temperature controller 102. A program (sequence) for controlling the power fed to the heater 62 and the blower 66 is embedded into the temperature controller 102, so that the temperature inside the film deposition chamber 60 is efficiently converged to a set temperature (predetermined temperature). The power fed to the heater 62 is controlled by control signals from the temperature controller 102 via a power controller such as a thyristor 103. Further, the power fed to the blower 66 is controlled by control signals from the temperature controller 102 via a power controller such as an inverter 104.

In a case where the injector heater 77 is provided, the temperature controller 102 controls the power to be fed to the heater 62, the injector heater 77, and the blower 66 while feeding back the temperature detected by the temperature sensor 101. Further, another program (sequence) for controlling the power fed to the heater 62, the injector heater 77, and the blower 66 is embedded into the temperature controller 102, so that the temperature inside the film deposition chamber 60 is efficiently converged to a set temperature (predetermined temperature). The power fed to the injector heater 77 is also controlled by control signals from the temperature controller 102 via a power controller such as the thyristor 103.

In this embodiment, in a case of increasing the temperature of the wafer W to a predetermined temperature (film deposition temperature) when depositing the polyimide film on the wafer W, the temperature controller 102 receives signals from the temperature sensor 101 and controls the power to be fed to the heater 62 and the cooling mechanism 65 based on the received signals. Then, the control part 100 controls the heating quantity of the heater 62 and the cooling quantity of the blower 66. Thereby, during a process of increasing the temperature of the wafer W in a case where the film deposition temperature is in a low temperature range (e.g., approximately 200° C.), the time for converging the temperature of the wafer W to the film deposition temperature (i.e., the time for performing the below-described recovery step) can be shortened. In addition, the stability of the temperature of the wafer W can be improved after the temperature of the wafer W is converged.

The feed mechanism 70 includes a source gas feeding part 71 and an injector 72 provided inside the film deposition chamber 60. The injector 72 includes a feeding tube 73a. The source gas feeding part 71 is connected to the feeding tube 73a of the injector 72.

In this embodiment, the feed mechanism 70 may include a first source gas feeding part 71a and a second source gas feeding part 71b. The first and the second source gas feeding parts 71a, 71b are connected to the injector 72 (feeding tube 73a) via valves 71c, 71d, respectively. The first source gas feeding part 71a includes a first vaporizer 74a configured to vaporize, for example, a PMDA source material. Thus, the first source gas feeding part 71a can feed PMDA gas. The second source gas feeding part 71b includes a second vaporizer 74b configured to vaporize, for example, an ODA source material.

A feeding hole 75 is formed in the feeding tube 73a as an opening toward the inside of the film deposition chamber 60. The injector 72 feeds the first and the second source gases flowing from the source gas feeding part 71 to the feeding tube 73a into the film deposition chamber 60 via the feeding hole 75.

Further, the feeding tube 73a may be provided in a manner extending in a vertical direction. Further, plural feeding holes 75 may be formed in the feeding tube 73a. The feeding hole 75 may have various shapes such as a circular shape, an elliptical shape, or a rectangular shape.

It is preferable for the injector 72 to include an inner feeding tube 73b. The inner feeding tube 73b may be formed in a portion that is further upstream than a portion which the feeding hole of the feeding tube 73a is formed. Further, an opening 76 may be formed in the vicinity of a downstream side of the inner feeding tube 73b for feeding either the first or the second source gas to the inner space of the feeding tube 73a. The opening 76 may have various shapes such as a circular shape, an elliptical shape, or a rectangular shape.

With the inner feeding tube 73b having the above-described configuration, the first and the second source gases can be sufficiently mixed inside the inner space of the feeding tube 73a prior to feeding the first and the second source gases from the feeding hole 75 to the inside of the film deposition chamber 60.

The following embodiment is a case where the first source gas is fed to the feeding tube 73a and the second source gas is fed to the inner feeding tube 73b.

In this embodiment, the boat 44 may have multiple wafers W vertically accommodated therein at predetermined intervals. In this embodiment, the feeding tube 73a and the inner feeding tube 73b may be provided in a manner extending in a vertical direction. Further, assuming that a lower part of the feeding tube 73a corresponds to an upstream side and an upper part of the feeding tube 73a corresponds to a downstream side, the inner feeding tube 73b may be installed inside the feeding tube 73a in a position lower than the part which the feeding hole of the feeding tube 73a is formed. Further, the opening 76 for communicating with the inner space of the feeding tube 73a may be provided in the vicinity of an upper end part of the inner feeding tube 73b.

The feed mechanism 70 is configured to have, for example, the first source gas flow through the feeding tube 73a and the second source gas flow through the inner feeding tube 73b. The second source gas flows from the inner feeding tube 73b to the feeding tube 73a via the opening 76. Thereby, the first and the second source gases are mixed. In such a mixed state, the first and the second source gases are fed into the film deposition chamber 60 via the feeding hole 75.

An injector heater 77 may be provided in the vicinity of the feeding tube 73a for controlling the temperature inside the feeding tube 73a (injector 72). Further, as described above, the temperature of the wafer W inside the reaction tube 61 may be controlled by the injector heater 77 and the heater 62.

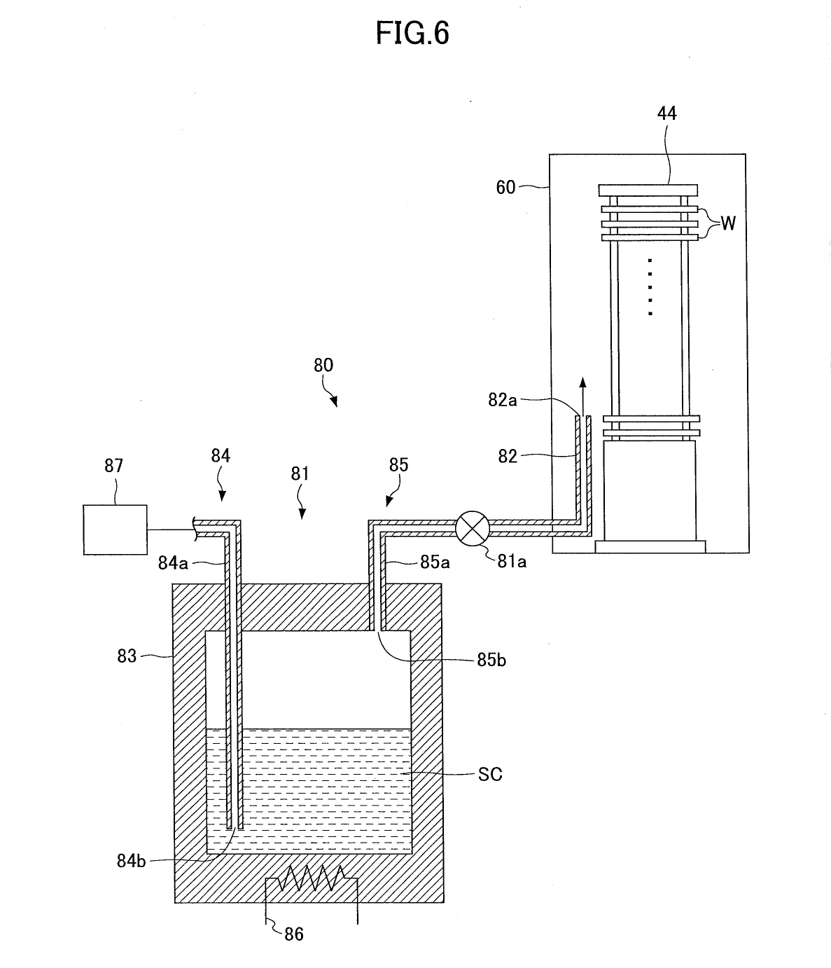

FIG. 6 is a schematic diagram illustrating a configuration of an adhesion accelerating agent feed mechanism 80 according to an embodiment of the present invention. It is to be noted that components other than those of the film deposition chamber 60, the boat 44, and the adhesion accelerating agent feed mechanism 80 are not illustrated in FIG. 6.

As illustrated in FIG. 6, the adhesion accelerating agent feed mechanism 80 includes an adhesion accelerating agent feeding part 81 and a feeding tube 82 provided inside the film deposition chamber 60. The adhesion accelerating agent feeding part 81 is connected to the feeding tube 82 via a valve 81a. The adhesion accelerating agent feed mechanism 80 feeds an adhesion accelerating agent gas (formed by vaporizing the below-described adhesion accelerating agent SC) into the film deposition chamber 60 and treats the surface of the wafer W with the adhesion accelerating agent gas.

The adhesion accelerating agent feeding part 81 includes a retaining container 83, a gas inlet part 84, and a gas outlet part 85.

The retaining container 83 is configured to have the adhesion accelerating agent SC (e.g., silane coupling agent) filled therein. A heating mechanism 86 is provided inside the retaining container 83. The adhesion coupling agent SC filled inside the retaining container 83 can be heated and vaporized by the heating mechanism 86. It is to be noted that a heater or the like may be used as the heating mechanism 86. As long as the retaining container 83 can be heated, the heating mechanism 86 can be arbitrarily positioned in a given part of the retaining container 83.

The gas inlet part 84 guides an adhesion accelerating agent carrier gas formed of an inert gas (e.g., nitrogen (N₂)) from an adhesion accelerating agent carrier gas feeding part 87, so that the adhesion accelerating agent gas can be carried by the adhesion accelerating agent carrier gas. The gas inlet part 84 includes a gas inlet tube 84a and a gas inlet port 84b. The gas inlet tube 84a is a tube for guiding the adhesion accelerating agent carrier gas from the outside to the inside of the retaining container 83. The gas inlet tube 84a is attached to a top surface of the retaining container 83 in a manner penetrating through the top surface of the retaining container 83 and extending vertically (i.e. from top to bottom of the retaining container 83) into the retaining container 83. Further, one end of the gas inlet tube 84a has an opening at the bottom part of the retaining container 83 whereas the other end of the gas inlet tube 84a is connected to the adhesion accelerating agent carrier gas feeding part 87 outside the retaining container 83. The gas inlet port 84b corresponds to the opening formed on the bottom end of the gas inlet tube 84a.

FIG. 6 illustrates the gas inlet port 84b positioned below the liquid surface of the adhesion accelerating agent SC for bubbling the adhesion accelerating agent SC with the adhesion accelerating agent carrier gas fed from the gas inlet port 84b. Alternatively, the gas inlet port 84b may be positioned above the liquid surface of the adhesion accelerating agent SC. In this case, the adhesion accelerating agent SC need not be bubbled with the adhesion accelerating agent carrier gas fed from the gas inlet port 84b.

The gas outlet part 85 guides the adhesion accelerating agent gas together with the adhesion accelerating agent carrier gas out from the retaining container 83. The gas outlet part 85 includes a gas outlet tube 85a and a gas outlet port 85b. The gas outlet tube 85a is a tube for guiding the adhesion accelerating agent gas and the adhesion accelerating agent carrier gas out from the retaining container 83. The gas outlet tube 85a is attached to the top surface of the retaining container 83 in a manner penetrating the top surface of the retaining container 83. Further, one end of the gas outlet tube 85a has an opening at an inner top part of the retaining container 83 whereas the other end of the gas outlet tube 85a is connected to a feeding tube 82 provided inside the film deposition chamber 60. The gas outlet port 85b corresponds to the opening formed on the bottom end of the gas outlet tube 85a.

The feeding tube 82, which is made of quartz, penetrates through the sidewall of the film deposition chamber 60 and bends in a manner extending upward. A feed opening 82a is formed at one end of the feeding tube 82 inside the film deposition chamber 60. The feeding tube 82 feeds the adhesion accelerating agent gas from the adhesion accelerating agent feeding part 81 to the inside of the film deposition chamber 60 via the feed opening 82a. It is preferable for the feed opening 82a to be provided in one part in the film deposition chamber 60 in the vicinity of the wafer(s) W mounted on the boat 44. Thereby, the adhesion accelerating agent gas from the feed opening 82a can be evenly dispersed inside the film deposition chamber 60.

The purge gas feed mechanism 90 includes a purge gas feeding part 91 and a purge gas feeding tube 92. The purge gas feeding part 91 is connected to the film deposition chamber 60 via the purge gas feeding tube 92. The purge gas feeding part 91 feeds a purge gas into the film deposition chamber 60. A valve 93 is provided at a midsection of the purge gas feeding tube 92 for communicating or disconnecting the purge gas feeding part 91 with respect to the inside of the film deposition chamber 60.

The exhaust mechanism 95 includes an exhaust device 96 and an exhaust pipe 97. The exhaust mechanism 95 is configured to evacuate gas from the inside of the film deposition chamber 60 via the exhaust pipe 97.

The control part 100 includes, for example, a processing part, a storage part, and a display part, which are not illustrated in FIG. 4. The processing part is, for example, a computer including a central processing unit (CPU). The storage part is a computer-readable recording medium formed of, for example, hard disks, on which a program for causing the processing part to execute various processes is recorded. The display part is formed of, for example, a computer screen (display). The processing unit reads a program recorded in the storage part and transmits control signals to components of the boat 44a (substrate holding part), the heater 62, the cooling mechanism 65, the feed mechanism 70, the adhesion accelerating agent feed mechanism 80, the purge gas feed mechanism 90, and the exhaust mechanism 95 in accordance with the program, thereby executing the below-described film deposition process.

As described above, the control part 100 may include, for example, the temperature sensor 101, the temperature controller 102, the thyristor 103, and the inverter 104.

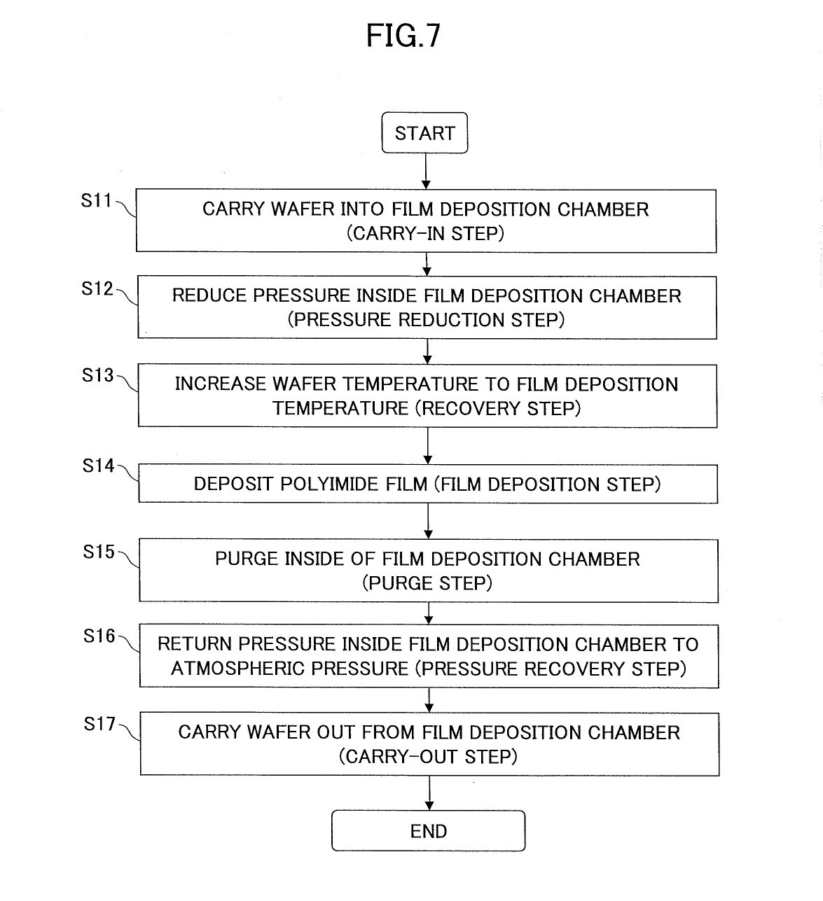

Next, a film deposition process using the above-described embodiment of the film deposition apparatus 10 is described. FIG. 7 is a flowchart for illustrating the process of steps including a film deposition process using the film deposition apparatus 10 according to this embodiment.

After the start of a film deposition process, the wafers W are carried into the film deposition chamber 60 (Step S11, carry-in step). In the embodiment of the film deposition apparatus 10 illustrated in FIG. 1, in the loading area 40, the wafers W may be loaded into the boat 44a with the transfer mechanism 47 and the boat 44a loaded with the wafers W may be placed on the lid body 43 with the boat conveying mechanism 45c. Then, the lid body 43 on which the boat 44a is placed is caused to move upward by the elevation mechanism 46 to be inserted into the film deposition chamber 60, so that the wafers W are carried into the film deposition chamber 60.

Then, the internal pressure of the film deposition chamber 60 is reduced (Step S12, pressure reduction step). By controlling the exhaust capability of the exhaust device 96 or a flow regulating valve (not illustrated) provided between the exhaust device 96 and the exhaust pipe 97, the amount by which the film deposition chamber 60 is evacuated via the exhaust pipe 97 is increased. The internal pressure of the film deposition chamber 60 is reduced from a predetermined pressure such as an atmospheric pressure (760 Torr) to, for example, 0.3 Torr.

Then, the temperature of the wafer(s) W is increased to a predetermined temperature (film deposition temperature) for depositing a polyimide film on the wafer W (Step S13, recovery step).

Immediately after the boat 44a is carried into the film deposition chamber 60, the temperature of the temperature sensor 101 provided in the film deposition chamber 60 is close to room temperature. Therefore, the wafer(s) W mounted on the boat 44a is heated to the film deposition temperature by supplying power to the heater 62.

In this embodiment, the heater 62 and the cooling mechanism 65 are controlled, so that the temperature of the wafer W is converged to the film deposition temperature. For example, the power supplied to the heater 62 can be controlled while the blow quantity (cooling quantity) of the blower 66 is maintained at a constant state (first control method). With the first control method, the power supplied to the heater 62 is increased to a point immediately before the temperature of the wafer W reaches the film deposition temperature while the flow rate of the blower 66 is maintained at a constant state. Then, the power supplied to the heater 62 is reduced to a point immediately before the temperature of the wafer W becomes stable at a desired film deposition temperature. As a result, the temperature of the wafer W is converged to the predetermined temperature. Accordingly, the time for converging the temperature of the wafer W to the film deposition temperature can be reduced, and the temperature of the wafer W can be stably controlled after the temperature of the wafer W is converged to the film deposition temperature.

Alternatively, the temperature of the wafer W may be converged to the film deposition temperature by reducing the power supplied to the heater 62 immediately before the temperature of the wafer W reaches the film deposition temperature while rapidly cooling the film deposition chamber 60 by increasing the flow rate of the blower 66 (second control method).

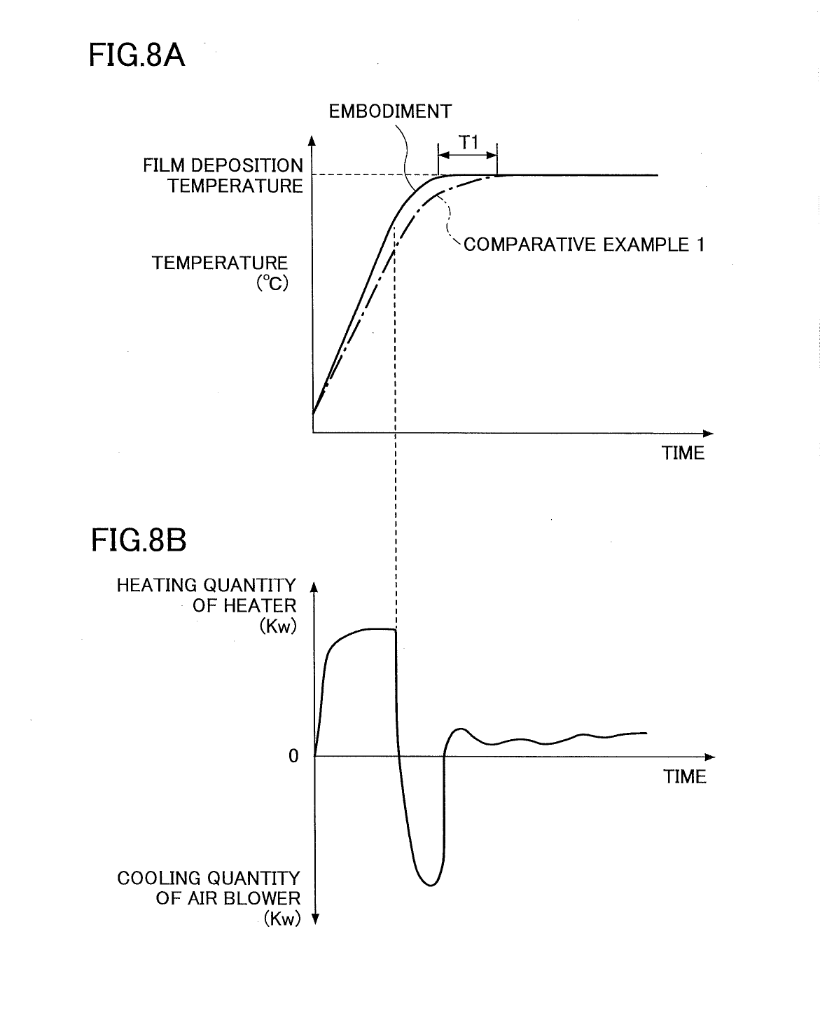

FIGS. 8A and 8B are graphs for describing an example of a method for controlling the heater 62 and the cooling mechanism 65 (second control method). FIG. 8A is a graph illustrating a comparison of the dependency of the temperature of the wafer W relative to time in a case where the cooling mechanism 65 is used according to an embodiment of the present invention (second control method) and a case where the cooling mechanism 65 is not used according to a comparative example 1. Further, FIG. 8B is a graph illustrating the dependency of the heating quantity of the heater 62 and the dependency of the cooling quantity of the blower 66 relative to time according to an embodiment of the present invention.

With the second control method, the power supplied to the heater 62 (heating quantity) is reduced to 0 immediately before the temperature of the wafer W reaches the film deposition temperature while the flow rate of the blower 66 (cooling quantity) is increased. Thereby, the time for the temperature of the wafer W to converge to the film deposition temperature can be reduced to time T (see FIG. 8) compared to the comparative example 1.

Further, in the recovery step according to an embodiment of the present invention, the surface of the wafer W is treated with an adhesion accelerating agent. That is, in addition to heating the wafer with the heater 62, the surface of the wafer W is treated with an adhesion accelerating agent gas fed into the film deposition chamber 60 by the adhesion accelerating agent feed mechanism 80.

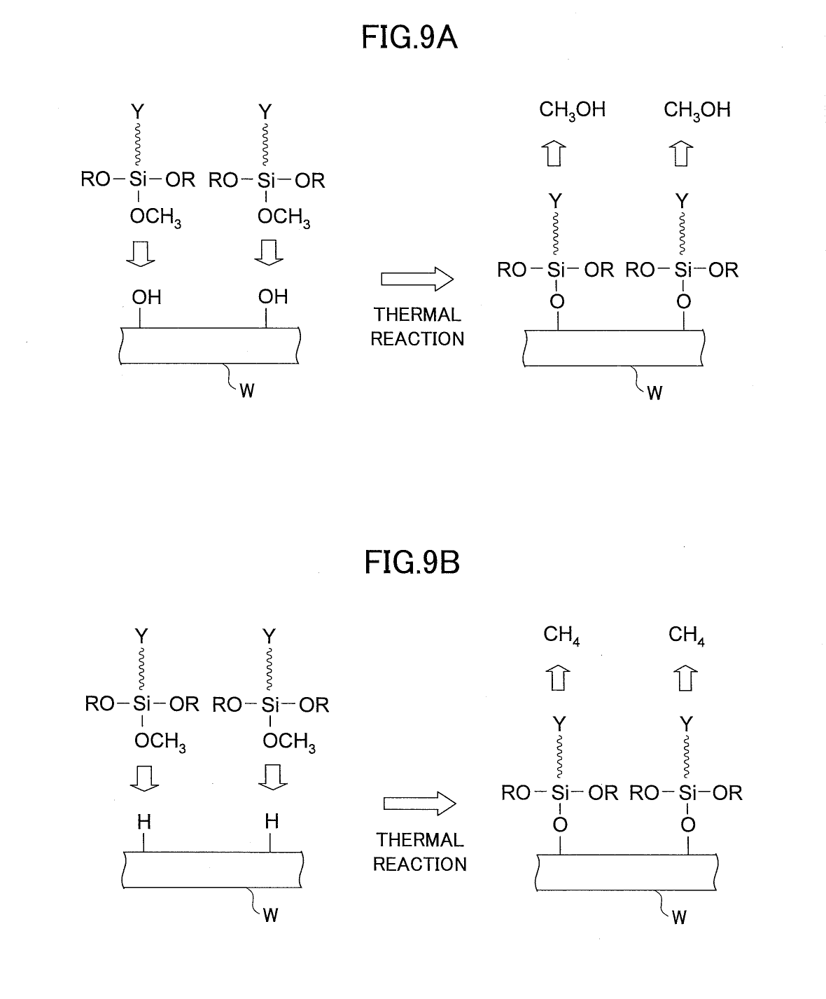

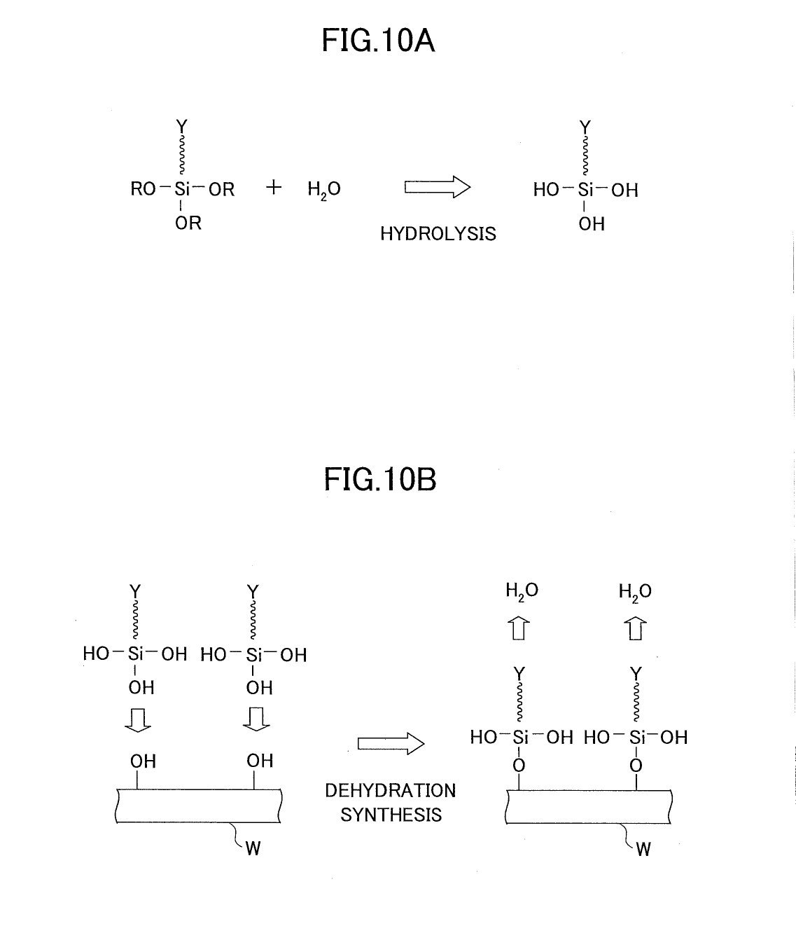

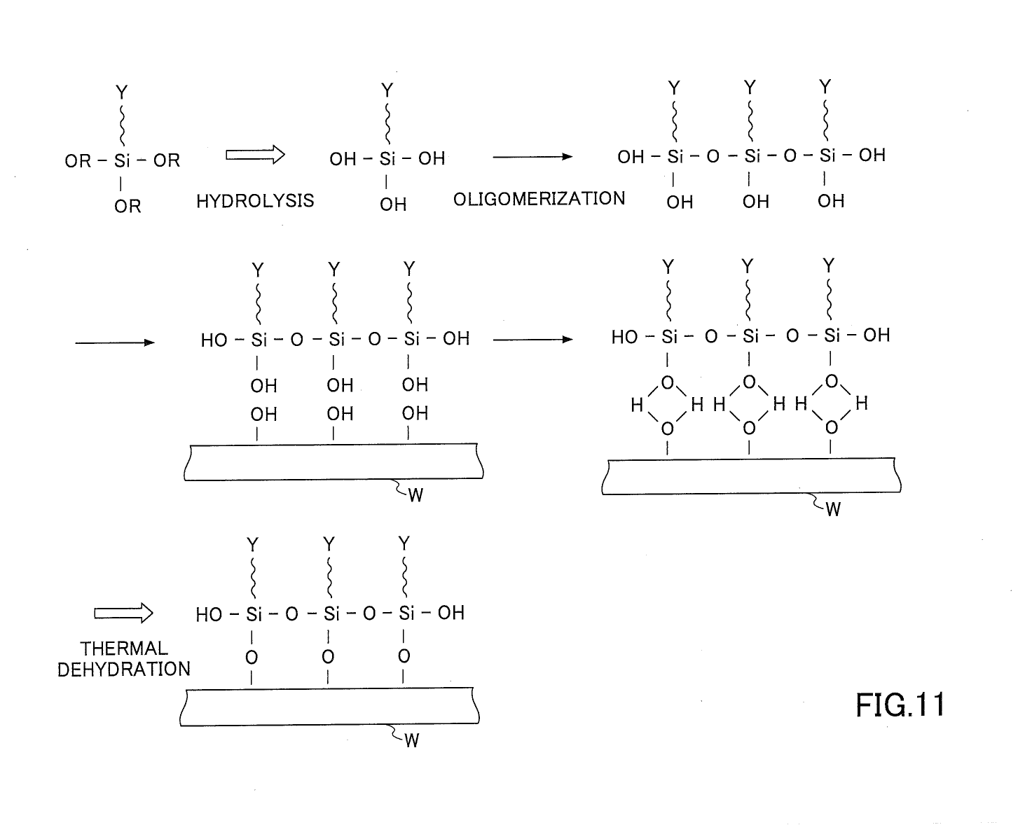

FIGS. 9A and 9B are schematic diagrams illustrating the reaction generated on the surface of the wafer W in a case where a silane coupling agent is used as the adhesion accelerating agent according to an embodiment of the present invention. FIGS. 10A-11 are schematic diagrams illustrating the reaction generated on the surface of the wafer W in a case where a silane coupling agent and a water vapor are used according to comparative example 2.

It is preferable to use organosilane having molecules containing an alkoxy group (RO— (R; alkyl group)) as the silane coupling agent. FIGS. 9A and 9B illustrate an example where organosilane having molecules containing, for example, a methoxy group (CH₃O—) is used. As illustrated in FIG. 9A, in a case of using a Si wafer having a hydroxyl group (—OH) terminated surface, methanol (CH₃OH) is generated by a thermal reaction between the methoxy group of the silane coupling agent and the hydroxyl group of the wafer surface. Thereby, the silane coupling agent adheres to the wafer surface. As illustrated in FIG. 9B, in a case of using a Si wafer having a hydrogen (H) terminated surface, methane (CH₄) is generated by a thermal reaction between the methoxy group of the silane coupling agent and the hydrogen atoms of the wafer surface. Thereby, the silane coupling agent adheres to the wafer surface.

On the other hand, with the comparative example 2, a silane coupling agent having molecules containing, for example, an alkoxy group and a water vapor are used. As illustrated in FIG. 10A, hydrolysis occurs between the alkoxy group of the silane coupling agent and the water vapor in the atmosphere. Thereby, the alkoxy group of the silane coupling agent becomes a hydroxyl group (—OH). Accordingly, in a case where a Si wafer having a hydroxyl group (—OH) terminated surface is used as the wafer W, dehydration synthesis occurs between the alkoxy group of the silane coupling agent and the hydroxyl group of the wafer surface. Thereby, the silane coupling agent adheres to the wafer surface.

Alternatively, as illustrated in FIG. 11, a silane coupling agent may have an alkoxy group changed to a hydroxyl group by hydrolysis with water vapor and then oglimerized by a polymerization reaction. When the oglimerized silane coupling agent is brought closer to the Si wafer having a hydroxyl group (—OH) surface, the silane coupling agent is further subjected to thermal dehydration via an intermediate (intermediary). Thereby, the silane coupling agent adheres to the wafer surface. Accordingly, with the comparative example 2, there is a risk of generation of particles due to the polymerization.

On the other hand, with the above-described embodiment of the present invention, generation of particles can be prevented because the silane coupling agent is not polymerized.

Further, because water vapor is used in the comparative example 2, the residual water vapor remaining inside the film deposition chamber may cause ring-opening of a five-membered ring of PMDA as illustrated in the following chemical formula 1.

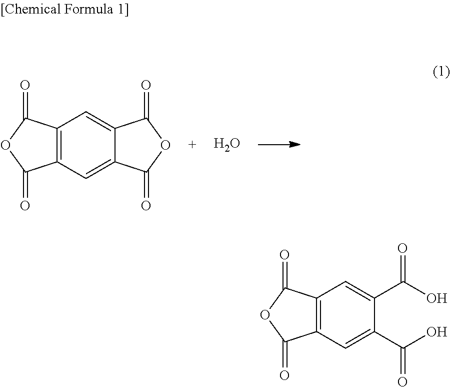 [SMILES: O=c1oc(=O)c2cc3c(=O)oc(=O)c3cc12 ; O ; O=C(O)c1cc2c(cc1C(=O)O)C(=O)OC2=O]

If a five-membered ring of PMDA is opened, the property of the PMDA would change, and the reaction of PMDA and ODA would not progress in the film deposition step. As a result, a polyimide film cannot be deposited. On the other hand, according to an embodiment of the present invention, the reaction of PMDA and ODA can progress in the film deposition step because water vapor is not used. As a result, a polyimide film can be deposited.

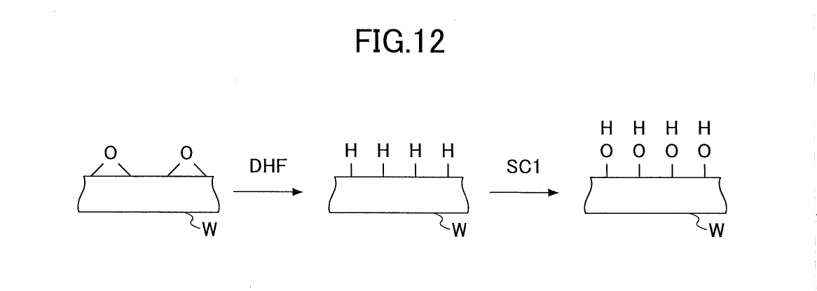

With the comparative example 2 where a Si wafer having a hydroxyl group-terminated surface is used, it is necessary to terminate the surface of a wafer W formed of Si with hydrogen atoms by dilute hydrofluoric (DHF) cleaning, and then terminate the surface of the wafer W with a hydroxyl group by ammonia peroxide (standard clean, (SC) 1) cleaning as illustrated in FIG. 12. Accordingly, the comparative example 2 requires to perform adjustment of the terminated wafer surface for a greater number of times (greater number of steps). On the other hand, with the embodiment of the present invention, both a wafer having a hydroxyl group-terminated surface or a wafer having a hydrogen-terminated surface can be used as the wafer W. Accordingly, the embodiment of the present invention can reduce the number of steps for adjusting the terminated wafer surface.

Next, a film deposition process according to a comparative example 3 is described where a surface treatment apparatus (which is provided separate from a film deposition apparatus) is used to perform surface treatment with an adhesion accelerating agent gas.

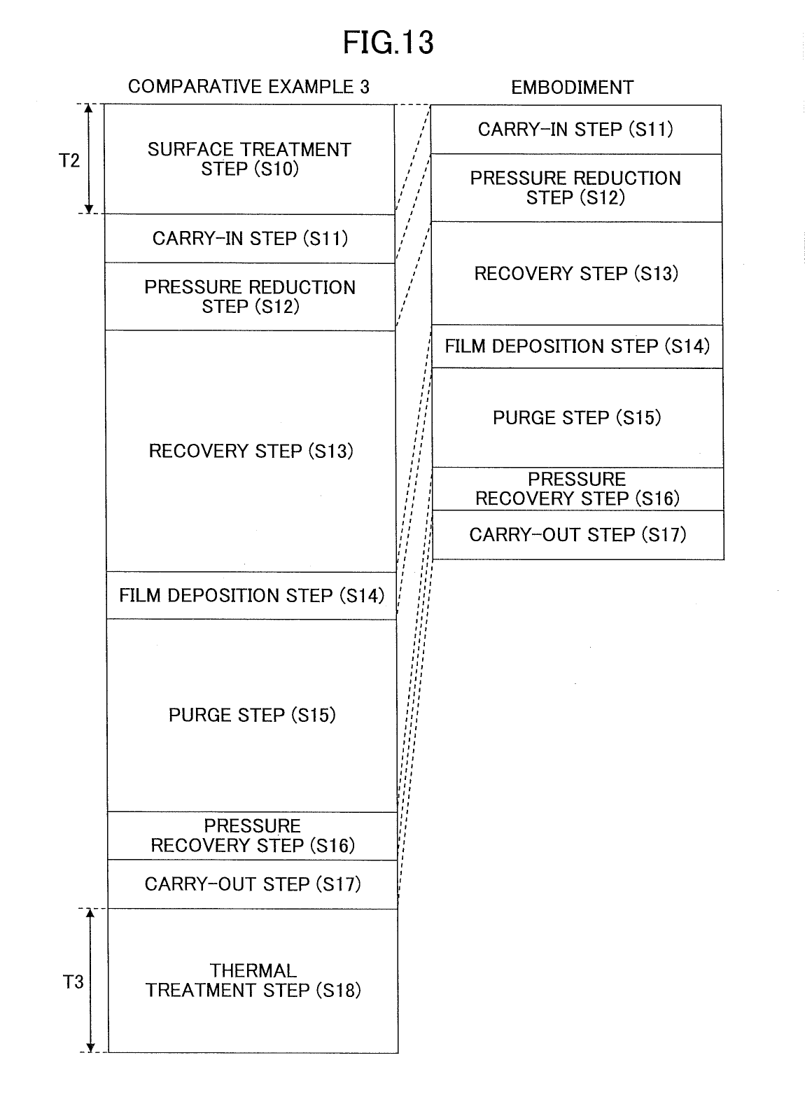

FIG. 13 is a time chart illustrating a comparison between a film deposition process according to an embodiment of the present invention and a film deposition process according to the comparative example 3. With the comparative example 3, a surface treatment step (Step S10) needs to be performed on a wafer W by using a surface treatment apparatus or the like (which is provided separate from a film deposition apparatus) prior to performing a carry-in step (Step S11). Accordingly, the film deposition process of this embodiment (right side of FIG. 13) can be performed in a shorter time T2 to an extent equivalent to the time in which surface treatment is performed by the surface treatment apparatus of the comparative example 3 (left side of FIG. 13). As a result, the number of film-deposited wafers per unit of time can be increased.

Next, a polyimide film is deposited (Step S14, film deposition step).

A first flow rate F1 at which the first source gas (PMDA gas) is caused to flow to the feeding tube 73a and a second flow rate F2 at which the second source gas (ODA gas) is caused to flow to the inner feeding tube 73b are determined in advance by the control part 100. The first source gas is caused to flow from the first source gas feeding part 71a to the feeding tube 73a at the determined first flow rate F1 and the second source gas is caused to flow from the second source gas feeding part 71b to the inner feeding tube 73b at the determined second flow rate F2 while the wafers W are being rotated by the rotation mechanism 49. Thereby, the first and the second source gases are mixed at a predetermined mixture ratio and fed into the film deposition chamber 60. PMDA and ODA are subjected to a polymerization reaction on the top surfaces of the wafers W so that a polyimide film is deposited on the top surfaces of the wafers W. Specifically, for example, the first flow rate F1 may be 900 sccm and the second flow rate F2 may be 900 sccm.

The polymerization reaction of PMDA and ODA at this point follows the following chemical formula (2).

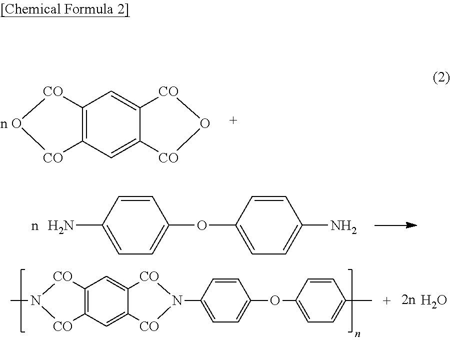

In the film deposition step (Step S14), because the source gases are fed from a single point next to the wafer W, it is easy for the source gases to reach a peripheral portion of the wafer W but difficult to reach a center portion of the wafer W. Therefore, the flow rate of the source gases, the pressure inside the film deposition chamber 60, and the interval between the wafers W are to be controlled in order to make the film deposition rate at the peripheral portion and the film deposition rate at the center portion substantially the same, so that the film thickness can be even throughout the wafer W.

If the entire surface of the wafer W is not treated with the adhesion accelerating agent, the film deposition rate would be different even if the source gases reach the surface of the wafer W. According to this embodiment, the entire surface of the wafer W can be evenly treated (applied) with the adhesion accelerating agent by the recovery step (Step S13) performed immediately before the film deposition step. Accordingly, the film deposition rate can be made even throughout the entire surface of the wafer W. As a result, film thickness can be made even throughout the entire surface of the wafer W.

In the case where the film deposition process of the comparative example 3 was performed (i.e. performing surface treatment with adhesion accelerating agent gas by using a surface treatment apparatus that is separate from the film deposition chamber 60), the evenness of the film thickness of the deposited polyimide film (in-plane evenness: 1σ) was 3.5%. On the other hand, in the case where the film deposition process according to this embodiment was performed (i.e. performing surface treatment with adhesion accelerating agent gas inside the film deposition chamber 60), the evenness of the film thickness of the deposited polyimide film (in-plane evenness: 1σ) was 2.1%. Hence, with this embodiment, the film thickness (in-plane thickness) of the wafer W can be made even.

Then, the feeding of PMDA gas from the first source gas feeding part 71a and the feeding of ODA gas from the second source gas feeding part 71b are stopped, and the inside of the film deposition chamber 60 is purged with purge gas (Step S15, purge step).

More specifically, the feeding of the first source gas from the first source gas feeding part 71a is stopped by closing the valve 71c. Further, the feeding of the second source gas from the second source gas feeding part 71b is stopped by closing the valve 71d. Further, purge gas replaces the source gases inside the film deposition chamber 60 by controlling the purge gas feed mechanism 90 and the exhaust mechanism 95.

For example, by controlling the exhaust capability of the exhaust device 96 or adjusting a flow rate adjustment valve (not illustrated) provided between the exhaust device 96 and the exhaust pipe 97, the amount by which the film deposition chamber 60 is evacuated can be increased. Thereby, the pressure inside the film deposition chamber 60 can be reduced to, for example, 0.3 Torr. Then, the valve 93 is opened and purge gas is fed inside the film deposition chamber 60 from the purge gas feed mechanism 90 until the internal pressure inside the film deposition chamber 60 reaches, for example, 5.0 Torr. Thereby, the source gases inside the film deposition chamber 60 can be replaced with purge gas. In addition, after performing decompression of the exhaust mechanism 95 and feeding of purge gas from the purge gas feed mechanism 90 once, respectively, the decompression of the exhaust mechanism 95 and the feeding of purge gas may be performed for a further number of times. Thereby, the source gases inside the film deposition chamber 60 can be more positively replaced with purge gas.

According to an embodiment of the present invention, the polyimide film deposited on the wafer W may be thermally treated by a heater in the purge step. The thermal treatment is performed for imidizing parts of the deposited film that are not imidized after the film deposition step. Because polyimide has a high insulating property, the insulating property of the deposited polyimide film can be improved by increasing the imidization rate (i.e. proportion of polyimide in the deposited film).

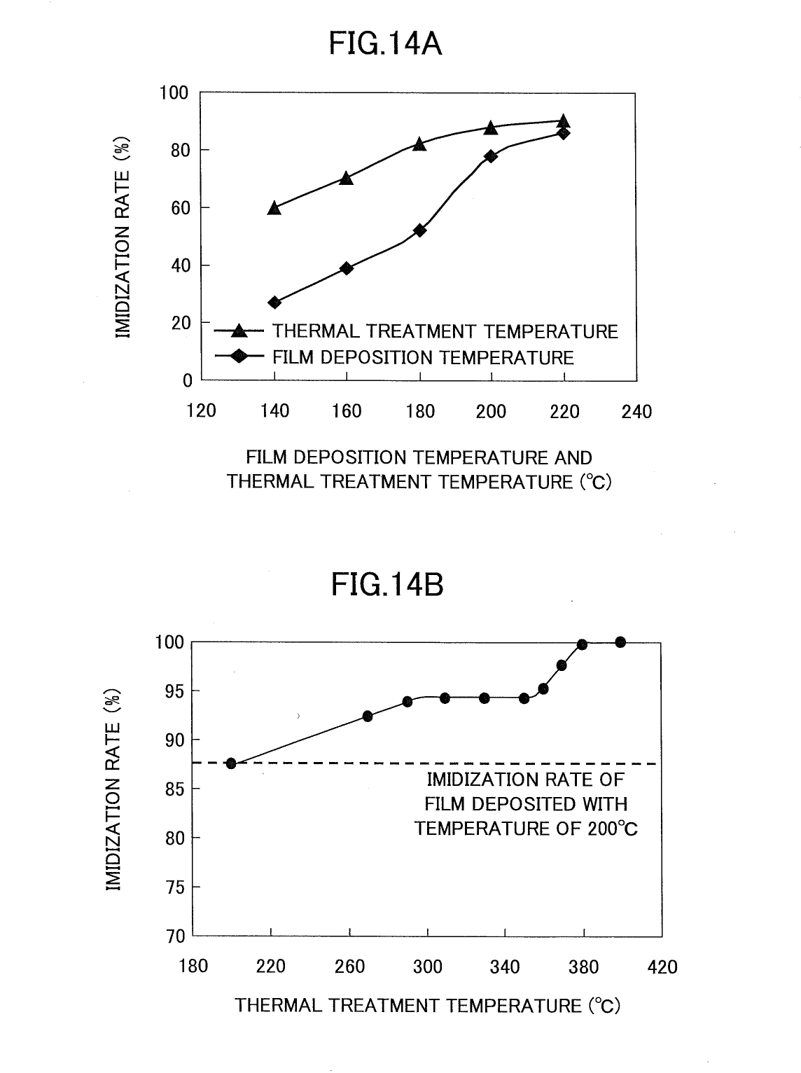

FIGS. 14A and 14B are graphs for describing the dependency of the imidization rate of the polyimide film with respect to a film deposition temperature and a thermal treatment temperature. FIG. 14A illustrates the dependency of the imidization rate of the polyimide film with respect to the film deposition temperature and the thermal treatment temperature. FIG. 14B illustrates the dependency of the imidization rate of the polyimide film with respect to the thermal treatment temperature. The imidization rate of FIGS. 14A and 14B is obtained by analyzing the polyimide film with a Fourier Transform Infra-Red spectroscopy (FT-IR) method after the film deposition step.

As illustrated in FIG. 14A, the imidization rate decreases in a case where both the film deposition temperature and the thermal treatment temperature are less than 200° C. Therefore, it is preferable for the film deposition temperature and the thermal treatment temperature to be 200° C. or more. Thereby, a polyimide film having an excellent insulating property can be obtained.

As illustrated in FIG. 14B, the imidization rate increases along with the increase of the thermal treatment temperature in a case where the thermal treatment temperature ranges from 200° C. to 300° C. In a case where the thermal treatment temperature ranges from 300° C. to 350° C., the imidization rate hardly changes due to the affect of glass transition temperature in the vicinity of 350° C. In a case where the thermal treatment temperature ranges from 350° C. to 380° C., the imidization rate rapidly increases along with the increase of the thermal treatment temperature. The imidization rate reaches approximately 100% where the thermal treatment temperature is 380° C. Therefore, it is preferable for the thermal treatment temperature to be 380° C. or more (e.g., 400° C. or more). Thereby, the polyimide film can be imidized almost completely. Thus, the polyimide film can attain a greater insulating property.

The results of examining leak current and imidization are illustrated in Table 1 in a case of performing thermal treatment on a polyimide film deposited in a film deposition temperature of 200° C. where the thermal treatment is performed for 10 minutes, 20 minutes, 40 minutes, and 70 minutes, respectively. Table 1 illustrates the leak current when an electric field of 1.0 MV/cm is applied.

TABLE 1

| | | | | |
|---|---|---|---|---|
| THERMAL TREATMENT | 10 | 20 | 40 | 70 |
| TIME (MINUTES) | | | | |
| LEAK CURRENT WITH | 3.61 | 1.74 | 1.80 | 1.79 |
| RESPECT TO ELECTRIC | | | | |
| FIELD OF 1.0 MV/cm (nA/cm²) | | | | |
| IMIDIZATION (%) | 83 | 85 | 87 | 87 |

As illustrated in Table 1, even in a case where the thermal treatment time is reduced from 70 minutes to 40 minutes, and to 20 minutes, the leak current hardly changes and remains in a range of 1.74 nA/cm² to 1.80 nA/cm². However, in a case where the thermal treatment time is 10 minutes, the leak current steeply increases to 3.61 nA/cm². Therefore, it is preferable for the thermal treatment time to be 20 minutes or more. Thereby, leak current can be reduced, and the insulating property of the polyimide film can be improved.

Further, it is preferable to control the wafer temperature with the heater 62 and the cooling mechanism 65 in a case of performing thermal treatment in the purge step (Step S15).

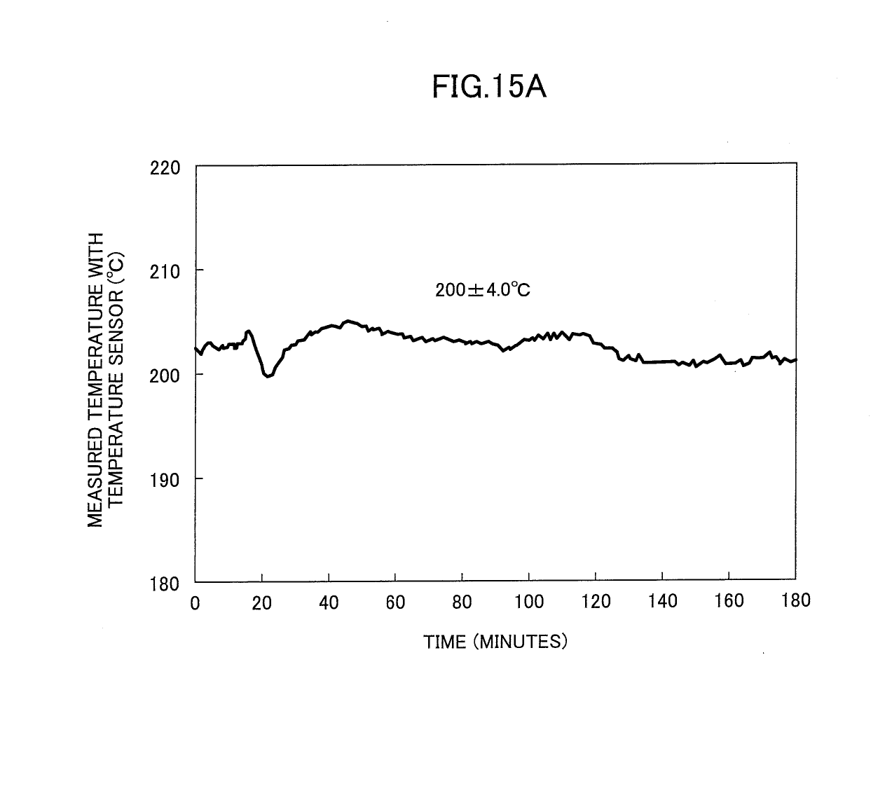

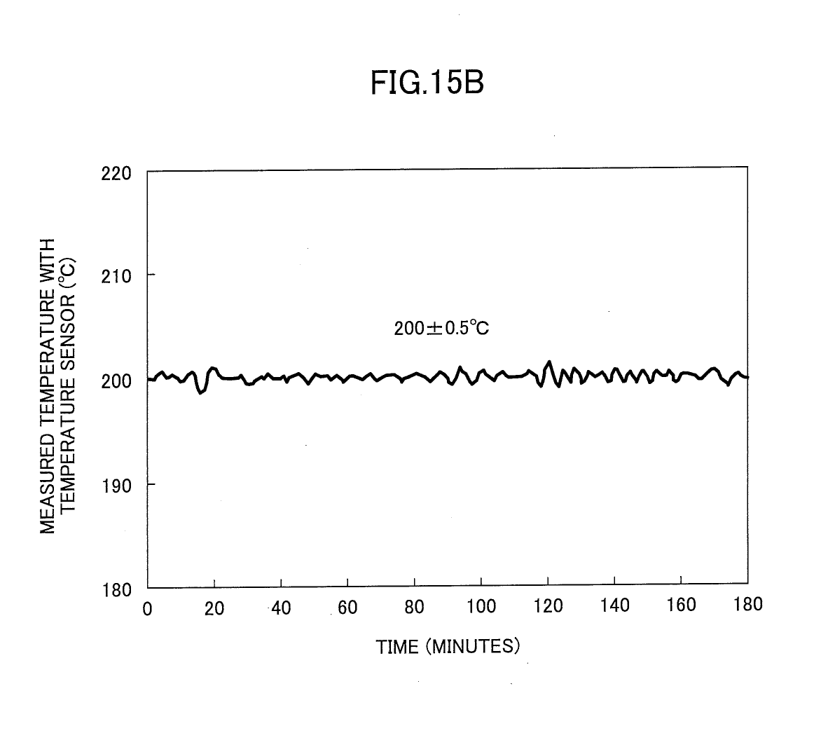

FIGS. 15A and 15B are graphs illustrating a comparison between a case of using the cooling mechanism 65 and a case of not using the cooling mechanism where the temperature is measured by the temperature sensor 101 provided in the film deposition chamber 60 during a period between carrying the boat 44a into the film deposition chamber 60 and carrying the boat 44a out from the film deposition chamber 60. FIG. 15A illustrates the case of not using the cooling mechanism 65. FIG. 15B illustrate the case of using the cooling mechanism 65.

As illustrated in FIG. 15A, in the case of not using the cooling mechanism 65 where a target temperature is set to 200° C., the temperature measured by the temperature sensor 101 varies ±4.0° C. with respect to the target temperature. As illustrated in FIG. 15B, in the case of using the cooling mechanism 65 where the target temperature is set to 200° C., the temperature measured by the temperature sensor 101 only slightly varies ±0.5° C. with respect to the target temperature. Therefore, even in the temperature range of 200° C., temperature can be controlled with high precision by using the heater 62 and the cooling mechanism 65.

In a case of assuming that the above-described comparative example 3 uses a thermal treatment apparatus separate from the film deposition apparatus to perform the thermal treatment for imidization, the thermal treatment for imidization (Step S18) must be performed by the thermal treatment apparatus after the carry-out step (Step S17 of FIG. 13), that is, after performing a series of steps constituting the film deposition process. The film deposition process according an embodiment of the present invention (right side of FIG. 13) can be performed in a shorter time than that of the comparative example 3 (left side of FIG. 13) to an extent equivalent to the time (T3) of the thermal treatment step performed by the thermal treatment apparatus of the comparative example 3. As a result, the number of wafers subjected to film deposition per unit of time can be increased.

Then, the internal pressure of the film deposition chamber 60 is returned to an atmospheric pressure (Step S16, pressure recovery step). By controlling the exhaust capability of the exhaust device 96 or the flow regulating valve (not illustrated) provided between the exhaust device 96 and the exhaust pipe 97, the amount by which the film deposition chamber 60 is evacuated is reduced. The internal pressure of the film deposition chamber 60 is returned from, for example, 0.3 Torr to, for example, an atmospheric pressure (760 Torr).

As long as the thermal process of the deposited polyimide film is performed inside the film deposition chamber 60 before the below-described carry-out step, the thermal process may be performed during the pressure recovery step or after the pressure recovery step.

Then, the wafers W are carried out of the film deposition chamber 60 (Step S17, carry-out step). In the case of the film deposition apparatus 10 illustrated in FIG. 1, for example, the lid body 43 on which the boat 44a is placed may be caused to move downward by the elevation mechanism 46 to be carried out from inside the film deposition chamber 60 to the loading area 40. Then, the wafers W are transferred from the boat 44a placed on the carried-out lid body 43 to the container 21 by the transfer mechanism 47. Thereby, the wafers W are carried out of the film deposition chamber 60. Thereafter, the film deposition process ends.

In the case of successively subjecting multiple batches to a film deposition process, a further transfer of the wafers W from the container 21 to the boat 44 is performed in the loading area 40 by the transfer mechanism 47, and the process returns again to Step S11 to subject the next batch to a film deposition process.

### Modified Example of First Embodiment

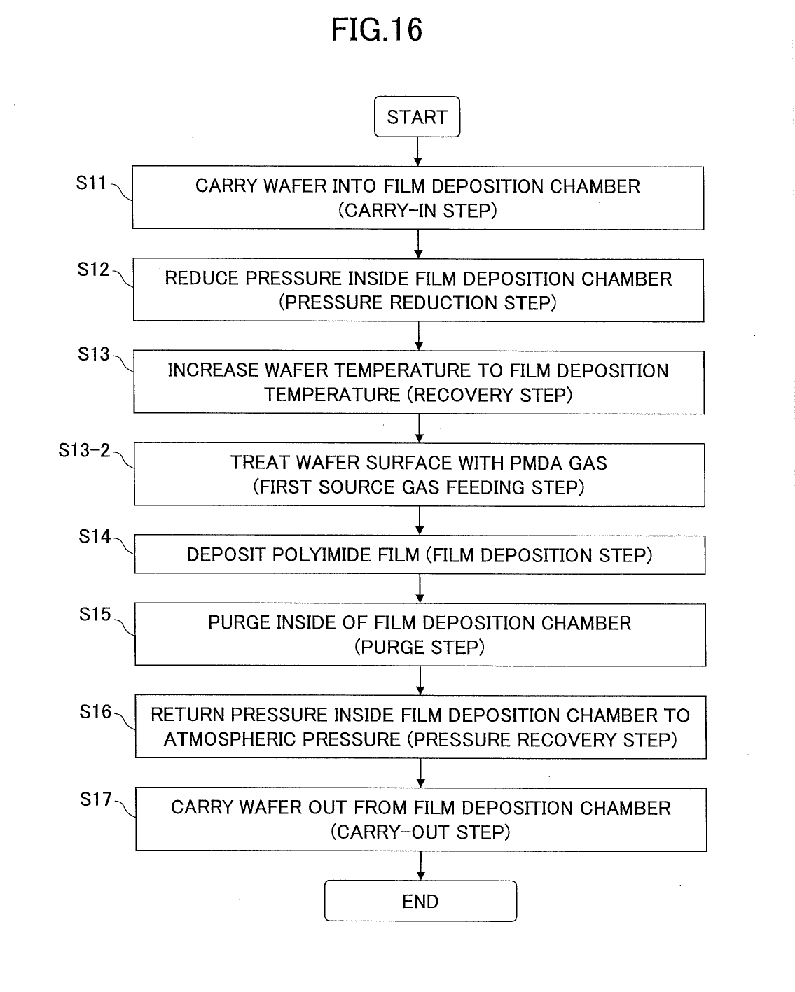

Next, a film deposition apparatus according to a modified example of the first embodiment is described with reference to FIG. 16.

With the film deposition apparatus of the modified example, unlike the above-described film deposition apparatus 10 of the first embodiment, the substrate is treated with the first source gas after treating the surface of the substrate with the adhesion accelerating agent gas but before depositing the polyimide film on the substrate. It is to be noted that the description of the film deposition apparatus 10 of the first embodiment may be applied to the description of the film deposition apparatus of the modified example. Thus, detailed description of the film deposition apparatus of the modified example is omitted.

FIG. 16 is a flowchart illustrating steps included in a film deposition process performed by the film deposition apparatus according to the modified example.

With the modified example, the wafer surface is treated with the first source gas (Step S13-2, first source gas feeding step) by supplying the first source gas from the first source gas feeding part 71a after the recovery step (Step S13) but before the film deposition step (Step S14).

In a case where the first source gas feeding step is added, the evenness of the film thickness of the deposited polyimide film (in-plane evenness: 1σ) was reduced from 14.3% to 2.1% under substantially the same processing conditions of the first embodiment. This is regarded to be the result of PMDA adhering to the entire surface of the wafer owing to a reaction between the PMDA and the functional group provided on the side opposite of the Si wafer surface on which the silane coupling agent is adhered. Therefore, in the film deposition step, polyimide film can be evenly deposited throughout the entire surface of the wafer W.

### Second Embodiment

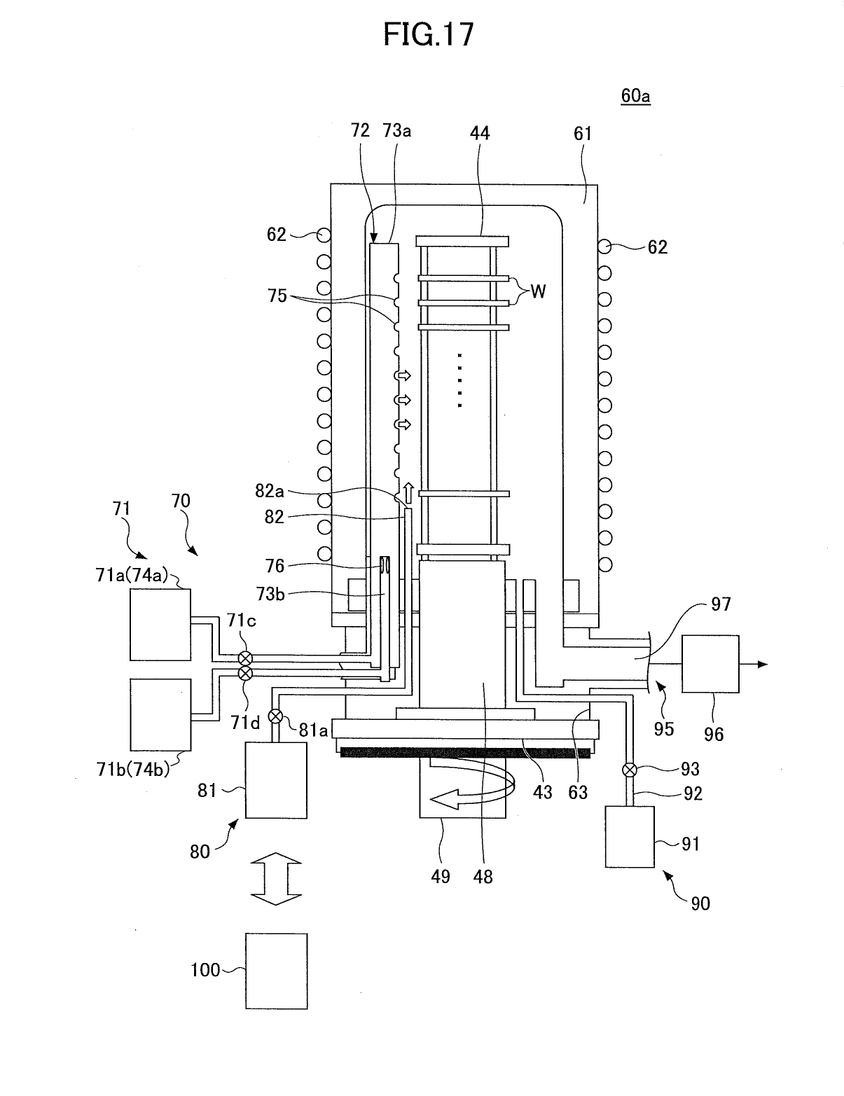

Next, a film deposition apparatus according to a second embodiment of the present invention is described with reference to FIG. 17.

The film deposition apparatus of the second embodiment is different from the film deposition apparatus 10 of the first embodiment in that, a film deposition chamber 60a of the second embodiment does not include a cooling mechanism. Therefore, the film deposition apparatus of the second embodiment has the same components/mechanisms as those of the film deposition apparatus 10 of the first embodiment except for the film deposition chamber 60a. Thus, detailed description of components/mechanisms other than the film deposition chamber 60a is omitted. In the description and drawing of the second embodiment, like components/mechanisms are denoted with like reference numerals as those of the first embodiment and are not further described.

FIG. 17 is a cross-sectional view illustrating a configuration of the film deposition chamber 60a according to the second embodiment. Similar to the first embodiment, the film deposition chamber 60a may be, for example, a vertical furnace that accommodates multiple substrates to be processed (treated), such as thin disk-shaped wafers W, and performs a predetermined process such as CVD on the substrates to be processed. The film deposition chamber 60a includes the reaction tube 61, the heater 62, the feed mechanism 70, the adhesion accelerating agent feed mechanism 80, the purge gas feed mechanism 90, and the exhaust mechanism 95. Although the reaction tube 61, the heater 62, the feed mechanism 70, the adhesion accelerating agent feed mechanism 80, the purge gas feed mechanism 90, and the exhaust mechanism 95 may have the same configuration as those of the first embodiment, no cooling mechanism is included in the film deposition chamber 60a.

Similar to the first embodiment, surface treatment may be performed by supplying an adhesion accelerating agent from the adhesion accelerating agent feed mechanism 80 in the recovery step in the film deposition process of the second embodiment. Thereby, the film quality of the deposited polyimide film can be improved, and the number of film-deposited wafers per unit of time can be increased.

Similar to the first embodiment, the deposited polyimide film can be thermally treated in the purge step of the film deposition process of the second embodiment. Likewise, the film quality of the deposited polyimide film can be improved, and the number of film-deposited wafers per unit of time can be increased.

Further, the present invention is not limited to these embodiments, but various variations and modifications may be made without departing from the scope of the present invention.

What is claimed is:

1. A film deposition apparatus comprising:
a film deposition chamber into which a substrate is carried;
a heating mechanism that heats the substrate carried into the film deposition chamber;
an adhesion accelerating agent feed mechanism that feeds an adhesion accelerating agent gas into the film deposition chamber; and
a control part that controls the heating mechanism and the adhesion accelerating agent feed mechanism;
wherein when depositing a polyimide film on the substrate by feeding a first source gas formed of dianhydride and a second source gas formed of diamine into the film deposition chamber, the control part is configured to control the adhesion accelerating agent feed mechanism to treat a surface of the substrate with the adhesion accelerating agent gas by feeding the adhesion accelerating agent gas into the film deposition chamber until the substrate is heated to a predetermined temperature for depositing the polyimide film.

2. The film deposition apparatus as claimed in claim 1, wherein the adhesion accelerating agent feed mechanism includes a feeding tube provided inside the film deposition chamber; wherein the feeding tube includes a feeding hole; wherein the feeding tube is configured to feed the adhesion accelerating agent gas into the film deposition chamber via the feeding hole.

3. The film deposition apparatus as claimed in claim 2, further comprising:
a substrate holding part configured to hold the substrate inside the film deposition container;
wherein the feeding hole is positioned in the vicinity of the substrate held by the substrate holding part.

4. The film deposition apparatus as claimed in claim 1, further comprising:
a first source gas feeding part configured to feed the first source gas into the film deposition chamber;
wherein the control part is configured to control the first source gas feeding part, so that the first source gas is fed into the film deposition chamber for treating the surface of the substrate with the first source gas after treating the surface of the substrate with the adhesion accelerating agent gas but before depositing the polyimide film.

5. The film deposition apparatus as claimed in claim 1, further comprising:
a cooling mechanism configured to cool the film deposition chamber by delivering air to the film deposition chamber;
wherein the control part is configured to control a heating quantity of the heating mechanism and a cooling quantity of the cooling mechanism in a case of increasing the substrate to the predetermined temperature.

6. The film deposition apparatus as claimed in claim 1, wherein the control part is configured to control the heating mechanism, so that thermal treatment is performed on the substrate after depositing the polyimide film on the substrate.

7. The film deposition apparatus as claimed in claim 6, further comprising:
an exhaust mechanism configured to evacuate gas inside the film deposition chamber;
wherein the control part is configured to control the heating mechanism, so that the thermal treatment is performed on the substrate after depositing the polyimide film on the substrate, evacuating the gas inside the film deposition chamber, and replacing the gas inside the film deposition chamber with a purge gas by supplying the purge gas from a purge gas feed mechanism.
